(19) United States
(12) Patent Application Publication
(10) Pub. No.: US 2025/0169125 A1
(43) Pub. Date: May 22, 2025

(54) HIGH ELECTRON MOBILITY TRANSISTOR

(71) Applicant: HiPer Semiconductor Inc., Taipei City (TW)

(72) Inventors: PO-JUNG LIN, Hsinchu County (TW); WEI-CHEN YANG, Hsinchu County (TW)

(73) Assignee: HiPer Semiconductor Inc., Taipei City (TW)

(21) Appl. No.: 18/923,571

(22) Filed: Oct. 22, 2024

(30) Foreign Application Priority Data
Nov. 20, 2023 (TW) 112144721

(51) Int. Cl. H01L 29/06; H01L 29/20; H01L 29/778

(52) U.S. Cl. CPC H10D 62/106; H10D 30/475; H10D 62/8503

(57) ABSTRACT

A high electron mobility transistor includes a substrate, a nucleation layer, a buffer layer, a channel layer, and a barrier layer. The buffer layer includes a first buffer region, a second buffer region and a third buffer region. The first buffer region includes a first III-nitride stacked layer disposed on the nucleation layer and a second III-nitride stacked layer disposed on the first III-nitride stacked layer. The second buffer region is doped with carbon and iron. The third buffer region is doped with carbon and iron and has a carbon concentration greater than an iron concentration of the third buffer region. The second III-nitride stacked layer is doped with carbon and iron and has a carbon concentration greater than an iron concentration of the second III-nitride stacked layer.

### BACKGROUND OF THE INVENTION

### Technical Field

The present invention relates generally to a high electron mobility transistor, and more particularly to a high electron mobility transistor that is doped with carbon (C) and iron (Fe).

### Description of Related Art

A high electron mobility transistor (HEMT) is typically a structure having a heterojunction formed on a substrate, wherein a two-dimensional electron gas (2-DEG) is formed on the heterojunction between two materials with different energy gaps. As the HEMT makes use of the 2-DEG having a high electron mobility as a carrier channel of the transistor, the HEMT has features of a high breakdown voltage, the high electron mobility, a low on-resistance, and a low input capacitance, thereby the HEMT could be widely applied to high power semiconductor devices.

In order to improve the breakdown voltage of components, doping is generally performed on a buffer layer of the HEMT. For example, by performing carbon doping on the buffer layer, the breakdown voltage of the HEMT could be effectively improved. However, carbon doping would simultaneously influence the operational efficiency of the HEMT. Therefore, how to provide a high electron mobility transistor that could improve the breakdown voltage without influencing the operational efficiency, is a problem needed to be solved in the industry.

### BRIEF SUMMARY OF THE INVENTION

In view of the above, the primary objective of the present invention is to provide a high electron mobility transistor that could improve the breakdown voltage without influencing the operational efficiency.

The present invention provides a high electron mobility transistor including a substrate, a nucleation layer, a buffer layer, a channel layer and a barrier layer. The nucleation layer is disposed on the substrate. The buffer layer includes a first buffer region, a second buffer region, and a third buffer region. The first buffer region includes a first III-nitride stacked layer and a second III-nitride stacked layer. The first III-nitride stacked layer is disposed on the nucleation layer. The second III-nitride stacked layer is disposed on the first III-nitride stacked layer. The second buffer region is disposed on the first buffer region and is doped with carbon (C) and iron (Fe). The third buffer region is disposed on the second buffer region and is doped with carbon (C) and iron (Fe). The channel layer is disposed on the buffer layer. The barrier layer is disposed on the channel layer. The third buffer region is located between the second buffer region and the channel layer. A carbon (C) concentration of the third buffer region is greater than an iron (Fe) concentration of the third buffer region. The iron (Fe) concentration of the third buffer region gradually decreases in a direction from the second buffer region to the channel layer. An average Al composition of the first III-nitride stacked layer is greater than an average Al composition of the second III-nitride stacked layer. The second III-nitride stacked layer is doped with carbon (C) and iron (Fe). A carbon (C) concentration of the second III-nitride stacked layer is greater than an iron (Fe) concentration of the second III-nitride stacked layer.

In an embodiment, the second buffer region includes a first buffer sub-layer. A carbon (C) concentration of the first buffer sub-layer is greater than an iron (Fe) concentration of the first buffer sub-layer.

In an embodiment, the second buffer region includes at least one second buffer sub-layer and at least one third buffer sub-layer that are stacked. A carbon (C) concentration of the at least one second buffer sub-layer is greater than an iron (Fe) concentration of the at least one second buffer sub-layer. An iron (Fe) concentration of the at least one third buffer sub-layer is greater than a carbon (C) concentration of the at least one third buffer sub-layer.

In an embodiment, a thickness of the at least one second buffer sub-layer is greater than a thickness of the at least one third buffer sub-layer.

In an embodiment, the carbon (C) concentration of the at least one third buffer sub-layer is less than 1E17 cm⁻³. The iron (Fe) concentration of the at least one third buffer sub-layer is greater than 1E17 cm⁻³.

In an embodiment, the carbon (C) concentration of the at least one second buffer sub-layer is greater than 5E18 cm⁻³.

In an embodiment, the second III-nitride stacked layer is located between the first III-nitride stacked layer and the second buffer region. The average Al composition of the first III-nitride stacked layer is greater than 25%. The average Al composition of the second III-nitride stacked layer is less than 25%.

In an embodiment, the first III-nitride stacked layer and the second III-nitride stacked layer respectively includes at least one III-nitride semiconductor layer made of Al_{X}Ga_{1-X}N (0≤X≤1).

In an embodiment, the channel layer is doped with iron (Fe). An iron (Fe) concentration of the channel layer decreases in a direction away from the buffer layer.

In an embodiment, a thickness of the third buffer region is between 1 nm and 1000 nm.

In an embodiment, the iron (Fe) concentration of the third buffer region near the channel layer ranges between 1E18 cm⁻³ and 1E17 cm⁻³.

In an embodiment, the channel layer forms a two-dimensional electron gas (2DEG) near an interface between the barrier layer and the channel layer. An iron (Fe) concentration of the channel layer near the interface between the barrier layer and the channel layer is less than 5E17 cm⁻³.

With the aforementioned design, by carbon doping and iron doping of the buffer layer, the breakdown voltage and the operational efficiency of the high electron mobility transistor could be improved. Additionally, the iron concentration of the third buffer region gradually decreases in the direction from the interface between the second buffer region and the third buffer region to the interface between the third buffer region and the channel layer, so that the influence of the iron doped third buffer region on the carrier concentration of the two-dimensional electron gas in the channel layer could be reduced.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a schematic sectional view of the high electron mobility transistor according to a first embodiment of the present invention;

FIG. 2 is a schematic view, showing the carbon concentration and iron concentration of the high electron mobility transistor in FIG. 1; and

FIG. 3 is a schematic view, showing the carbon concentration and iron concentration of the high electron mobility transistor according to a second embodiment of the present invention.

### DETAILED DESCRIPTION OF THE INVENTION

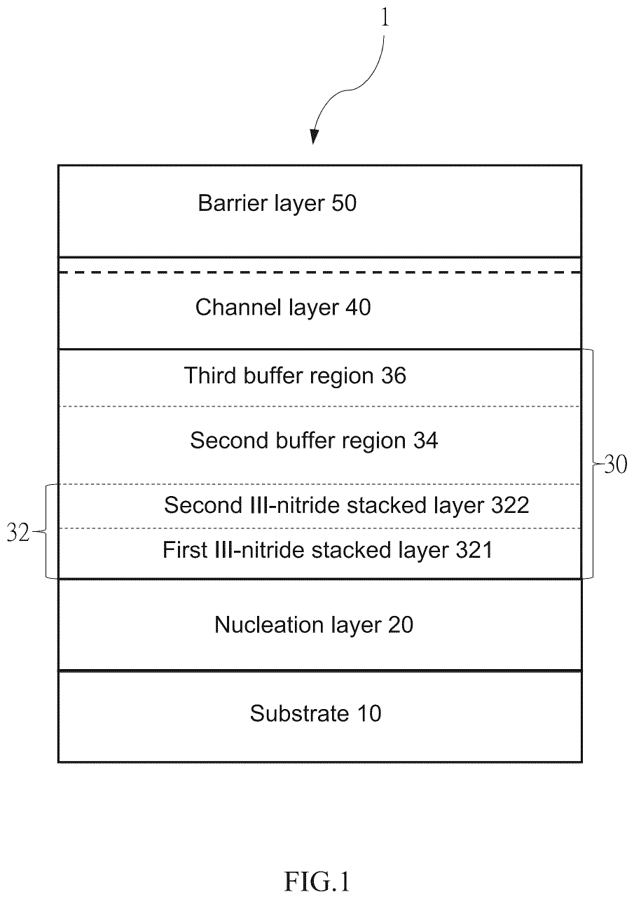

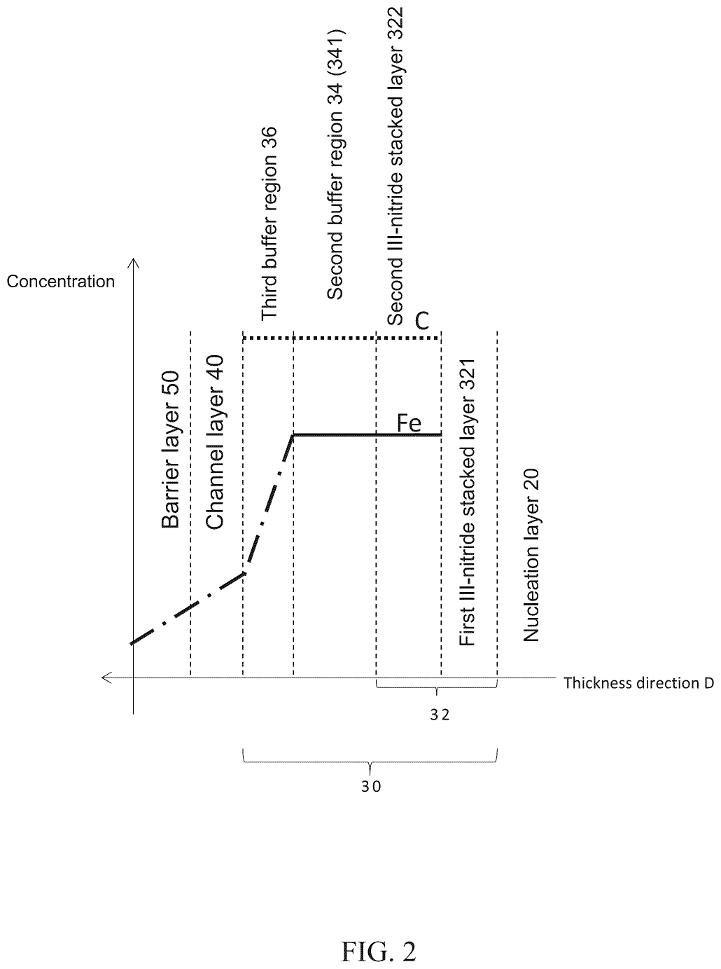

A high electron mobility transistor 1 according to a first embodiment of the present invention is illustrated in FIG. 1 and FIG. 2. The high electron mobility transistor 1 could be an enhancement mode high electron mobility transistor or a depletion mode high electron mobility transistor. The high electron mobility transistor 1 includes a substrate 10, a nucleation layer 20, a buffer layer 30, a channel layer 40, and a barrier layer 50. The substrate 10, the nucleation layer 20, the buffer layer 30, the channel layer 40, and the barrier layer 50 are sequentially disposed along a thickness direction D by stacking.

The channel layer 40 forms a two-dimensional electron gas 2DEG in the channel layer 40 near an interface between the channel layer 40 and the barrier layer 50. Additionally, the channel layer 40 is doped with iron (Fe). In the embodiment, an iron concentration of the channel layer 40 gradually decreases from an interface between the channel layer 40 and the buffer layer 30 in a direction away from the buffer layer 30. In the embodiment, the iron concentration of the channel layer 40 near the interface between the channel layer 40 and the barrier layer 50 is less than 5E17 cm⁻³. In the embodiment, a thickness of the barrier layer 50 is 20 nm, and a thickness of the channel layer 40 is 300 nm.

In the embodiment, the substrate 10 could be a silicon (Si) substrate, a gallium III-nitride (GaN) substrate, a silicon carbide (SiC) substrate, or a sapphire (Al₂O₃) substrate. The nucleation layer 20 could be an aluminum nitride (AlN) layer. The channel layer 40 could be an undoped gallium III-nitride (uGaN) channel layer. The barrier layer 50 could be, for example, an aluminum-gallium nitride (AlGaN) barrier layer, an aluminum nitride (AlN) barrier layer, an indium aluminum nitride (AlInN) barrier layer, an indium gallium aluminum nitride (AlInGaN) barrier layer.

The nucleation layer 20 is disposed on the substrate 10. The buffer layer 30 is disposed on the nucleation layer 20. The buffer layer 30 includes a first buffer region 32, a second buffer region 34, and a third buffer region 36. The first buffer region 32, the second buffer region 34, and the third buffer region 36 are sequentially disposed by stacking along the thickness direction D. The first buffer region 32 includes a first III-nitride stacked layer 321 and a second III-nitride stacked layer 322. The first III-nitride stacked layer 321 is disposed on the nucleation layer 20. The second III-nitride stacked layer 322 is disposed on the first III-nitride stacked layer 321.

The second III-nitride stacked layer 322 is located between the first III-nitride stacked layer 321 and the second buffer region 34. An average Al composition of the first III-nitride stacked layer 321 is greater than an average Al composition of the second III-nitride stacked layer 322. The average Al composition is an atomic percentage of the whole III-nitride stacked layer. The average Al composition of the first III-nitride stacked layer 321 is greater than 25%. The average Al composition of the second III-nitride stacked layer 322 is less than 25%. The first III-nitride stacked layer 321 and the second III-nitride stacked layer 322 respectively include at least one III-nitride semiconductor layer, wherein the at least one III-nitride semiconductor layer is made of Al_{X}Ga_{1-X}N (0≤X≤1).

In the embodiment, the second III-nitride stacked layer 322 is doped with carbon and iron, wherein a carbon concentration of the second III-nitride stacked layer 322 is greater than an iron concentration of the second III-nitride stacked layer 322. A thickness of the second III-nitride stacked layer 322 is greater than a thickness of the first III-nitride stacked layer 321. The first III-nitride stacked layer 321 could be formed by stacking a plurality of III-nitride semiconductor layers. The second III-nitride stacked layer 322 could be formed by stacking a plurality of III-nitride semiconductor layers.

Additionally, in the embodiment, the carbon concentration and the iron concentration of the second III-nitride stacked layer 322 are respectively maintained at a constant value along the thickness direction D. The carbon concentration of the second III-nitride stacked layer 322 is preferably greater than or equal to 5E18 cm⁻³. The iron concentration of the second III-nitride stacked layer 322 is preferably greater than or equal to 1E17 cm⁻³.

The second buffer region 34 is disposed on the first buffer region 32 and is doped with carbon and iron. In the embodiment, the second buffer region 34 could be a doped gallium III-nitride (doped GaN) layer. In the embodiment, a thickness of the second buffer region 34 is between 500 nm and 3000 nm. In the embodiment, a carbon concentration and an iron concentration of the second buffer region 34 are respectively maintained at a constant value along the thickness direction D. In the embodiment, the second buffer region 34 includes a first buffer sub-layer 341; the first buffer sub-layer 341 could be a gallium III-nitride (GaN) layer; a carbon concentration of the first buffer sub-layer 341 is greater than an iron concentration of the first buffer sub-layer 341, wherein the carbon concentration of the first buffer sub-layer 341 is preferably greater than or equal to 5E18 cm⁻³, and the iron concentration of the first buffer sub-layer 341 is preferably greater than or equal to 1E17 cm⁻³. Moreover, in the embodiment, the carbon concentration of the second III-nitride stacked layer 322 is substantially equal to the carbon concentration of the first buffer sub-layer 341, and the iron concentration of the second III-nitride stacked layer 322 is substantially equal to the iron concentration of the first buffer sub-layer 341.

Referring to FIG. 1 and FIG. 2 the third buffer region 36 is disposed on the second buffer region 34 and is doped with carbon and iron. The third buffer region 36 could be gallium III-nitride (GaN). The channel layer 40 is disposed on the third buffer region 36. The barrier layer 50 is disposed on the channel layer 40. The third buffer region 36 is located between the second buffer region 34 and the channel layer 40.

In the embodiment, iron elements of the third buffer region 36 comes from the diffusion of iron doping of the second buffer region 34, i.e., iron doping is not intentionally performed on the third buffer region 36. As shown in FIG. 2, a carbon concentration of the third buffer region 36 is greater than an iron concentration of the third buffer region 36. The carbon concentration of the third buffer region 36 is substantially maintained at a constant value along the thickness direction D. The carbon concentration of the third buffer region 36 is substantially equal to the carbon concentration of the second buffer region 34. The carbon concentration of the third buffer region 36 is preferably greater than or equal to 5E18 cm⁻³. In summary, through carbon doping and iron doping of the buffer layer 30, the breakdown voltage and the operational efficiency of the high electron mobility transistor 1 could be effectively improved.

In the embodiment, the iron concentration of the third buffer region 36 gradually decreases in a direction from the second buffer region 34 to the channel layer 40, i.e., the iron concentration of the third buffer region 36 gradually decreases from an interface between the second buffer region 34 and the third buffer region 36 to an interface between the third buffer region 36 and the channel layer 40. The iron concentration of the third buffer region 36 near the channel layer 40 ranges between 1E18 cm⁻³ and 1E17 cm⁻³. In this way, the fluence of iron doping of the third buffer region 36 on a carrier concentration of the two-dimensional electron gas 2DEG in the channel layer 40 could be reduced. Moreover, a thickness of the third buffer region 36 is between 1 nm and 1000 nm.

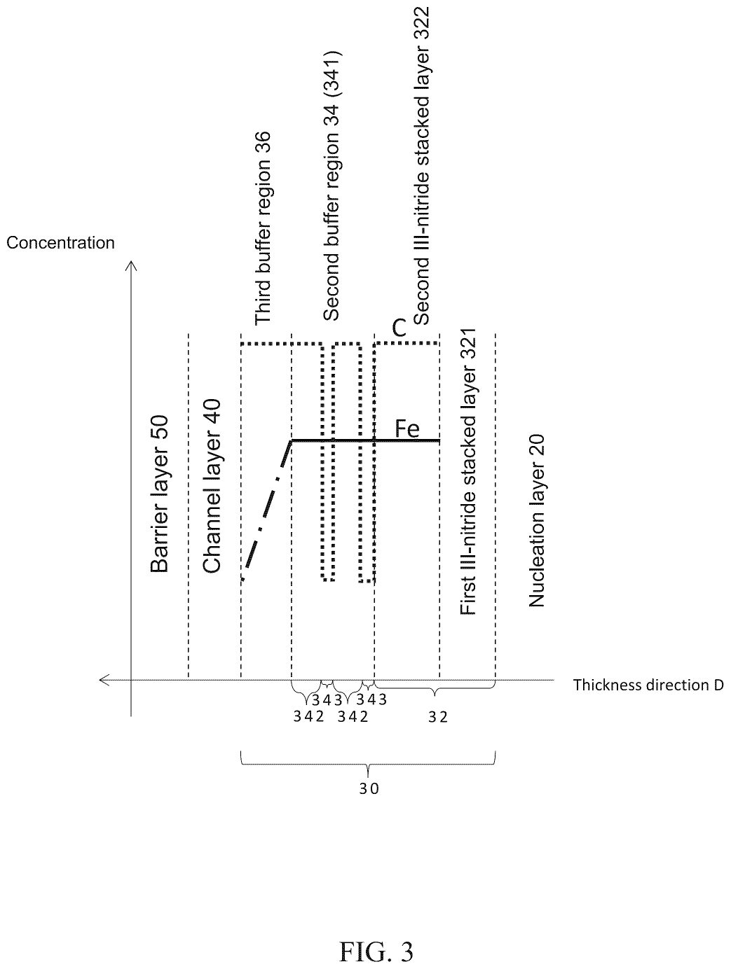

FIG. 3 is a schematic view, showing distributions of a carbon concentration and an iron concentration of a high electron mobility transistor according to a second embodiment of the present invention. The high electron mobility transistor of the second embodiment has almost the same structure as that of the high electron mobility transistor 1 of the first embodiment, except that the carbon concentration of the second buffer region 34 of the first embodiment is maintained at a constant value along the thickness direction D as an example for illustration, but the second buffer region 34 of the second embodiment could include at least one second buffer sub-layer 342 and at least one third buffer sub-layer 343 that are stacked. In other words, the second buffer sub-layer 342 is disposed on the third buffer sub-layer 343 to form a stacked layer, and the second buffer region 34 could include one stacked layer or a plurality of stacked layers.

The second buffer sub-layer 342 and the third buffer sub-layer 343 could be a gallium III-nitride (GaN) layer. A carbon concentration of the at least one second buffer sub-layer 342 is greater than an iron concentration of the at least one second buffer sub-layer 342. An iron concentration of the at least one third buffer sub-layer 343 is greater than a carbon concentration of the at least one third buffer sub-layer 343. A thickness of the at least one second buffer sub-layer 342 is greater than a thickness of the third buffer sub-layer 343. In the embodiment, the thickness of the at least one second buffer sub-layer 342 is between 2 times and 10 times of the thickness of the at least one third buffer sub-layer 343. Additionally, the carbon concentration of the at least one second buffer sub-layer 342 is greater than 5E18 cm⁻³ and the iron concentration of the at least one second buffer sub-layer 342 is greater than 1E17 cm⁻³. The carbon concentration and the iron concentration of the at least one second buffer sub-layer 342 are substantially maintained at a constant value along the thickness direction D. The carbon concentration of the second buffer sub-layer 342 is substantially equal to the carbon concentration of the first buffer region 32. The carbon concentration of the at least one third buffer sub-layer 343 is less than 1E17 cm⁻³ and the iron concentration of the at least one third buffer sub-layer 343 is greater than 1E17 cm⁻³. The carbon concentration and the iron concentration of the at least one third buffer sub-layer 343 are substantially maintained at a constant value along the thickness direction D. In this way, by alternatively stacking the at least one second buffer sub-layer 342 and the at least one third buffer sub-layer 343 which have different carbon concentrations, the effect of adjusting the structural stress of the high electron mobility transistor could be achieved.

With the aforementioned design, the breakdown voltage and the operational efficiency of the high electron mobility transistor could be improved by carbon doping and the iron doping of the buffer layer 30. Additionally, by the iron concentration of the third buffer region 36 gradually decreasing in the direction from the interface between the third buffer region 36 and the second buffer region 34 to the interface between the third buffer region 36 and the channel layer 40, the influence of iron doping of the third buffer region 36 on the carrier concentration of the two-dimensional electron gas 2DEG of the channel layer 40 could be reduced.

It must be pointed out that the embodiments described above are only some preferred embodiments of the present invention. All equivalent structures and methods which employ the concepts disclosed in this specification and the appended claims should fall within the scope of the present invention.

What is claimed is:

1. A high electron mobility transistor, comprising:
a substrate;
a nucleation layer disposed on the substrate;
a buffer layer, comprising:
a first buffer region comprising a first III-nitride stacked layer and a second III-nitride stacked layer, wherein the first III-nitride stacked layer is disposed on the nucleation layer, and the second III-nitride stacked layer is disposed on the first III-nitride stacked layer;
a second buffer region disposed on the first buffer region, wherein the second buffer region is doped with carbon (C) and iron (Fe); and
a third buffer region disposed on the second buffer region, wherein the third buffer region is doped with carbon (C) and iron (Fe);
a channel layer disposed on the buffer layer; and
a barrier layer disposed on the channel layer;
wherein the third buffer region is located between the second buffer region and the channel layer; a carbon (C) concentration of the third buffer region is greater than an iron (Fe) concentration of the third buffer region; the iron (Fe) concentration of the third buffer region gradually decreases in a direction from the second buffer region to the channel layer; an average Al composition of the first III-nitride stacked layer is greater than an average Al composition of the second III-nitride stacked layer;
wherein the second III-nitride stacked layer is doped with carbon (C) and iron (Fe); a carbon (C) concentration of the second III-nitride stacked layer is greater than an iron (Fe) concentration of the second III-nitride stacked layer.

2. The high electron mobility transistor as claimed in claim 1, wherein the second buffer region comprises a first buffer sub-layer; a carbon (C) concentration of the first buffer sub-layer is greater than an iron (Fe) concentration of the first buffer sub-layer.

3. The high electron mobility transistor as claimed in claim 1, wherein the second buffer region comprises at least one second buffer sub-layer and at least one third buffer sub-layer that are stacked; a carbon (C) concentration of the at least one second buffer sub-layer is greater than an iron (Fe) concentration of the at least one second buffer sub-layer; an iron (Fe) concentration of the at least one third buffer sub-layer is greater than a carbon (C) concentration of the at least one third buffer sub-layer.

4. The high electron mobility transistor as claimed in claim 3, wherein a thickness of the at least one second buffer sub-layer is greater than a thickness of the at least one third buffer sub-layer.

5. The high electron mobility transistor as claimed in claim 3, wherein the carbon (C) concentration of the at least one third buffer sub-layer is less than 1E17 cm⁻³; the iron (Fe) concentration of the at least one third buffer sub-layer is greater than 1E17 cm⁻³.

6. The high electron mobility transistor as claimed in claim 3, wherein the carbon (C) concentration of the at least one second buffer sub-layer is greater than 5E18 cm⁻³.

7. The high electron mobility transistor as claimed in claim 1, wherein the second III-nitride stacked layer is located between the first III-nitride stacked layer and the second buffer region; the average Al composition of the first III-nitride stacked layer is greater than 25%; the average Al composition of the second III-nitride stacked layer is less than 25%.

8. The high electron mobility transistor as claimed in claim 1, wherein the first III-nitride stacked layer and the second III-nitride stacked layer respectively comprise at least one III-nitride semiconductor layer made of Al_{X}Ga_{1-X}N (0≤X≤1).

9. The high electron mobility transistor as claimed in claim 1, wherein the channel layer is doped with iron (Fe); an iron (Fe) concentration of the channel layer decreases in a direction away from the buffer layer.

10. The high electron mobility transistor as claimed in claim 1, wherein a thickness of the third buffer region is between 1 nm and 1000 nm.

11. The high electron mobility transistor as claimed in claim 1, wherein the iron (Fe) concentration of the third buffer region near the channel layer ranges between 1E18 cm⁻³ and 1E17 cm⁻³.

12. The high electron mobility transistor as claimed in claim 1, wherein the channel layer forms a two-dimensional electron gas (2DEG) near an interface between the barrier layer and the channel layer; an iron (Fe) concentration of the channel layer near the interface between the barrier layer and the channel layer is less than 5E17 cm⁻³.
